(19) United States
(12) Patent Application Publication
(10) Pub. No.: US 2026/0011575 A1
(43) Pub. Date: Jan. 8, 2026

(54) METHOD OF MANUFACTURING SEMICONDUCTOR PACKAGE AND SEMICONDUCTOR PACKAGE

(71) Applicant: Samsung Electronics Co., Ltd., Suwon-si (KR)

(72) Inventors: Taejun JEON, Suwon-si (KR); Kundae YEOM, Suwon-si (KR); Wonil SEO, Suwon-si (KR); Jesung KIM, Suwon-si (KR); Sanghyeon LEE, Suwon-si (KR); Minwoo JEON, Suwon-si (KR); Hyunho CHU, Suwon-si (KR)

(73) Assignee: Samsung Electronics Co., Ltd., Suwon-si (KR)

(21) Appl. No.: 19/013,654

(22) Filed: Jan. 8, 2025

(30) Foreign Application Priority Data
Jul. 8, 2024 (KR) 10-2024-0089740

(51) Int. Cl. H01L 21/56; H01L 23/00; H01L 23/29; H01L 23/31; H01L 25/065; H10B 80/00; H10D 80/30

(52) U.S. Cl. CPC H01L 21/565; H01L 24/96; H01L 24/97; H01L 25/0657; H01L 23/295; H01L 23/3128; H01L 23/3135; H01L 24/13; H01L 24/16; H01L 24/32; H01L 24/48; H01L 24/73; H01L 2224/13147; H01L 2224/13553; H01L 2224/13611; H01L 2224/16225; H01L 2224/32145; H01L 2224/32225; H01L 2224/48149; H01L 2224/48227; H01L 2224/73204; H01L 2224/73265; H01L 2224/96; H01L 2224/97; H01L 2225/06506; H01L 2225/0651; H01L 2225/06562; H01L 2924/1815; H10B 80/00; H10D 80/30

(57) ABSTRACT

A method of manufacturing a semiconductor package may include disposing, in a lower mold, a substrate strip in which a plurality of semiconductor chips are arranged in a horizontal direction, providing, in an upper mold, a release film to which a first encapsulant is attached, allowing the upper mold and the lower mold to be proximate to each other such that a first encapsulant is adjacent to an upper surface of each of the plurality of semiconductor chips, injecting a second encapsulant into a space between the upper mold and the lower mold, heating the first encapsulant and the second encapsulant to form a molded structure including a first encapsulating layer and a second encapsulating layer, allowing the upper mold and the lower mold to be spaced from each other such that the molded structure is separated from the release film, and cutting the molded structure.

### CROSS-REFERENCE TO RELATED APPLICATION(S)

This application claims benefit of priority to Korean Patent Application No. 10-2024-0089740 filed on Jul. 8, 2024 in the Korean Intellectual Property Office, the disclosure of which is incorporated herein by reference in its entirety.

### BACKGROUND

At least some inventive concepts relate to a method of manufacturing a semiconductor package and/or a semiconductor package.

With a reduction in weight and an implementation of high performance of electronic devices, an amount of heat generated by semiconductor chips, having a high degree of integration, may increase, which may be associated with degradation in performance of semiconductor chips. Accordingly, there is demand for a semiconductor package technology capable of more effectively dissipating heat generated from semiconductor chips.

### SUMMARY

Some aspects of the present inventive concepts relate to a method of manufacturing a semiconductor package having improved productivity and reliability, and/or a semiconductor package.

According some example embodiments, a method of manufacturing a semiconductor package may include disposing a substrate strip on a lower mold, the substrate strip having a plurality of semiconductor chips arranged in a horizontal direction thereon, providing a release film on an upper mold the release film having a first encapsulant attached thereto, allowing the upper mold and the lower mold to be proximate to each other such that the first encapsulant is adjacent to an upper surface of each of the plurality of semiconductor chips, injecting a second encapsulant into a space at least partially defined between the upper mold and the lower mold, heating the first encapsulant and the second encapsulant to form a molded structure, the molded structure including a first encapsulating layer and a second encapsulating layer stacked on the substrate strip, the first encapsulant forming the first encapsulating layer, and the second encapsulant forming the second encapsulating layer, allowing the upper mold and the lower mold to be spaced from each other such that the molded structure is separated from the release film, and cutting the molded structure. A first distance from the substrate strip to an interface between the first encapsulating layer and the second encapsulating layer may be less than a second distance from the substrate to an upper surface of the plurality of semiconductor chips.

According some example embodiments, a method of manufacturing a semiconductor package may include disposing substrate strips on a lower mold, a plurality of semiconductor chips being arranged on the substrate strips, the substrate strips being on opposite sides of an injection hole of the lower mold, providing a release film on an upper mold, the release film having a first encapsulant attached thereto, allowing the upper mold and the lower mold to be proximate to each other such that the first encapsulant is aligned on the substrate strips, injecting a second encapsulant through the injection hole, and forming a first encapsulating layer and a second encapsulating layer by heating a space at least partially defined between the lower mold and the upper mold, the first encapsulating layer and the second encapsulating layer being stacked on the substrate strips. The first encapsulating layer may be formed by the first encapsulant flowing in a direction toward the lower mold. The second encapsulating layer may be formed by the second encapsulant flowing toward the opposite sides of the injection hole.

According to some example embodiments, a method of manufacturing a semiconductor package may include disposing a substrate strip on a lower mold, the substrate strip having a plurality of semiconductor chips are arranged thereon, providing a release film on an upper mold, the release film having a first encapsulant attached thereto, allowing the upper mold and the lower mold to be proximate to each other such that the first encapsulant is adjacent to the plurality of semiconductor chips, injecting a second encapsulant into a space at least partially defined between the upper mold and the lower mold, allowing the first encapsulant and the second encapsulant to simultaneously flow, and forming a first encapsulating layer and a second encapsulating layer in which the first encapsulant and the second encapsulant are cured, respectively. An interface between the first encapsulating layer and the second encapsulating layer may abut a side surface of the plurality of semiconductor chips.

According to some example embodiments, a semiconductor package may include a package substrate including interconnection patterns, a semiconductor chip on the package substrate, the semiconductor chip having a lower surface facing the package substrate, an upper surface opposite to the lower surface, and a side surface between the lower surface and the upper surface, a first molded layer at least partially covering the upper surface of the semiconductor chip and an upper side surface of the side surface of the semiconductor chip, the upper side surface adjacent to the upper surface, a second molded layer disposed between the package substrate and the first molded layer, the second molded layer at least partially covering a lower side surface, adjacent to the lower surface, of the side surface of the semiconductor chip, and connection bumps disposed below the package substrate, the connection bumps electrically connected to the interconnection patterns. An interface between the first molded layer and the second molded layer may include a first contact point in contact with the side surface of the semiconductor chip, and a second contact point in contact with external surfaces of the first and second molded layers. The interface between the first molded layer and the second molded layer may extend in a single direction, intersecting the side surface of the semiconductor chip between the first contact point and the second contact point.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a flowchart illustrating a method of manufacturing a semiconductor package according to some example embodiments;

FIGS. 2A and 2B are diagrams illustrating an operation S101 of FIG. 1;

FIGS. 3A and 3B are diagrams illustrating an operation S102 of FIG. 1;

FIG. 4 is a diagram illustrating an operation S103 of FIG. 1;

FIG. 5 is a diagram illustrating an operation S104 of FIG. 1;

FIG. 6 is a diagram illustrating an operation S105 of FIG. 1;

FIGS. 7A to 7D are diagrams illustrating a molded structure according to some example embodiments;

FIG. 8 is a diagram illustrating an operation S106 of FIG. 1;

FIG. 9 is a diagram illustrating an operation S107 of FIG. 1;

FIGS. 10A and 10B are diagrams illustrating a semiconductor package manufactured according to some example embodiments; and

FIG. 11 is a diagram illustrating a semiconductor package manufactured according to some example embodiments.

### DETAILED DESCRIPTION

Hereinafter, some example embodiments will be described in detail. Unless otherwise described, the terms such as “upper,” “upper portion,” “upper surface,” “lower,” “lower portion,” “lower surface,” and “side surface” are based on the drawings, and may vary depending on a direction in which a component is actually arranged.

In addition, ordinal numbers such as “first,” “second,” “third,” and the like may be used as labels for specific elements, operations, directions, and the like, to distinguish various elements, steps, directions, and the like from one another. A term, not described in the specification using “first,” “second,” and the like, may still be referred to as “first” or “second” in the claims. In addition, a term referenced by a particular ordinal number (for example, “first” in a particular claim) may be described elsewhere with a different ordinal number (for example, “second” in the specification or another claim).

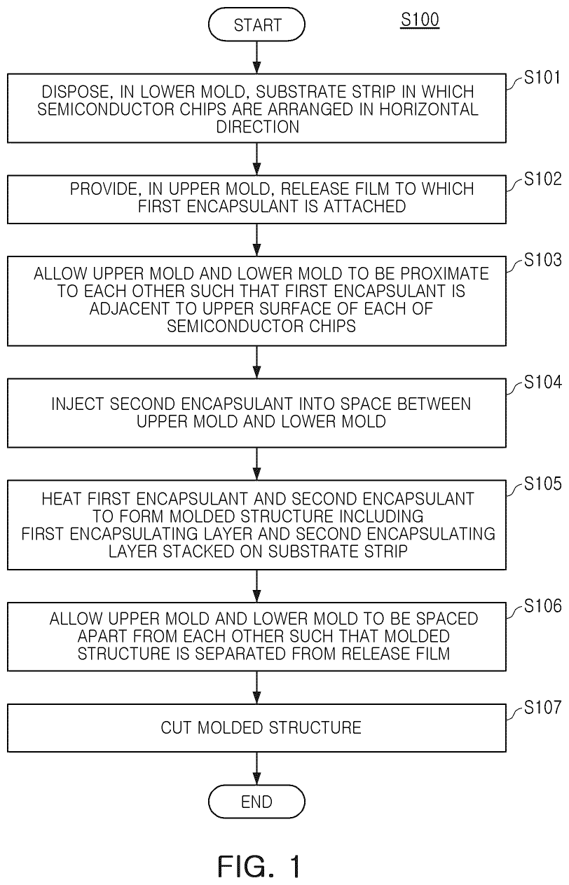

FIG. 1 is a flowchart illustrating a method S100 of manufacturing a semiconductor package according to some example embodiments.

Referring to FIG. 1, the method S100 of manufacturing a semiconductor package according to some example embodiments may include an operation S101 of disposing, in a lower mold, a substrate strip on which a plurality of semiconductor chips are arranged, an operation S102 of providing, in an upper mold, a release film to which a first encapsulant us attached, an operation S103 of allowing the upper mold and the lower mold to be proximate to each other such that the first encapsulant is adjacent to the plurality of semiconductor chips, an operation S104 of injecting the second encapsulant into a space between the upper mold and the lower mold, and an operation S105 of allowing the first encapsulant and the second encapsulant to flow and forming a first encapsulating layer and a second encapsulating layer in which the first encapsulant and the second encapsulant are cured, respectively. In some example embodiments, the method S100 of manufacturing a semiconductor package may further include an operation S106 of allowing the upper mold and the lower mold to be spaced apart from each other such that a molded structure is separated, and an operation S107 of cutting the molded structure.

According to example embodiments, a first encapsulant having relatively excellent thermal conductivity and a second encapsulant having relatively excellent filling properties may be simultaneously introduced into a mold to form molded layers having different materials, thereby improving productivity and reliability of a semiconductor package manufacturing process, and manufacturing a semiconductor package having improved heat dissipation properties.

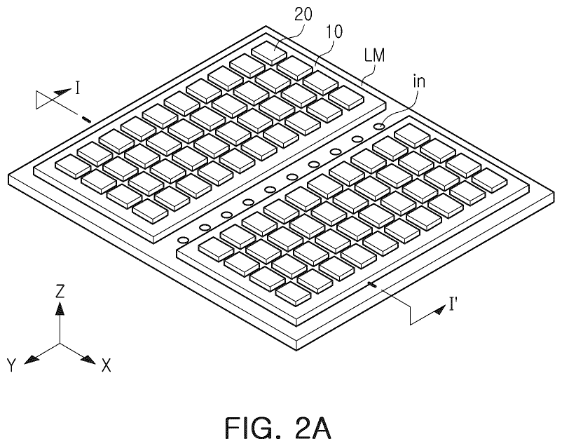

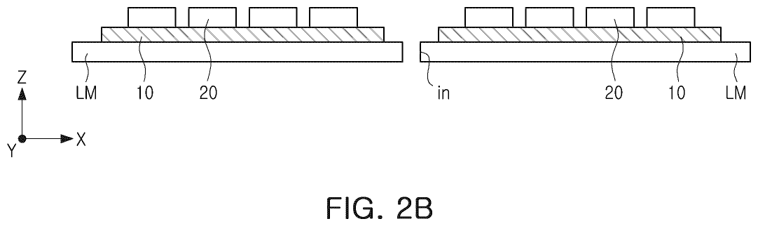

FIGS. 2A and 2B are diagrams illustrating an operation S101 of FIG. 1. FIG. 2A is a schematic perspective view of a lower mold LM on which a substrate strip 10 is disposed, and FIG. 2B is a cross-sectional view taken along line I-I′ of FIG. 2A.

Referring to FIGS. 2A and 2B, the substrate strip 10 on which a plurality of semiconductor chips 20 are arranged in a horizontal direction (X and Y-direction) may be disposed on the lower mold LM.

The lower mold LM may have a seating surface on which at least one substrate strip 10 is disposed. The seating surface may be a flat or substantially flat surface formed on an upper surface of the lower mold LM, or a cavity having (for example, defined or at least partially defined by) a flat or substantially flat bottom surface. The lower mold LM may include (for example, define) at least one injection hole in into which an encapsulant is injected in a subsequent operation. In the drawings, the injection hole in is illustrated as a hole passing through the lower mold LM, but the present inventive concepts are not limited thereto. For example, the injection hole in may be formed in (for example, defined by) an upper mold UM, or may be formed in (for example, defined or at least partially defined by) side surfaces of the upper mold UM and the lower mold LM coupled to each other.

The substrate strip 10 may include a plurality of package substrates (for example, a printed circuit board) connected (for example, integrally connected) to each other. The semiconductor chips 20 may be electrically connected to the substrate strip 10 in, for example, a flip-chip manner and/or a wire bonding manner. In some example embodiments, a plurality of substrate strips 10 may be disposed on opposite sides of the injection holes in arranged in one direction.

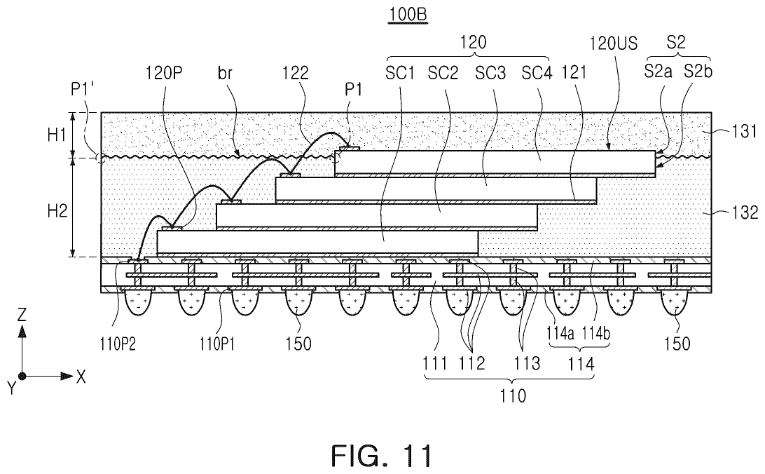

The plurality of semiconductor chips 20 may be disposed on a substrate strip 10 to be horizontally and/or vertically adjacent to each other. The plurality of semiconductor chips 20 may be greater than or less than the number of those illustrated in the drawings. For example, plurality of semiconductor chips 20 may include a logic chip including a central processing unit (CPU), a graphics processing unit (GPU), a field programmable gate array (FPGA), a digital signal processor (DSP), a cryptographic processor, a microprocessor, a microcontroller, an analog-to-digital converter, or an application-specific IC (ASIC), and/or a memory chip including a volatile memory such as a dynamic RAM (DRAM) and/or a static RAM (SRAM), and a non-volatile memory such as, for example, a phase change RAM (PRAM), a magnetic RAM (MRAM), a resistive RAM (RRAM), or a flash memory. In some example embodiments, each of the plurality of semiconductor chips 20 may include a plurality of stack chips stacked in a vertical direction (Z-direction) (for example, some example embodiments relating to FIG. 11). However, example embodiments are not limited thereto.

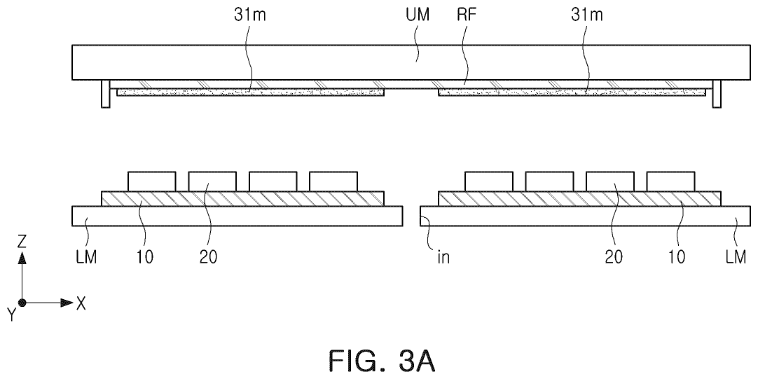

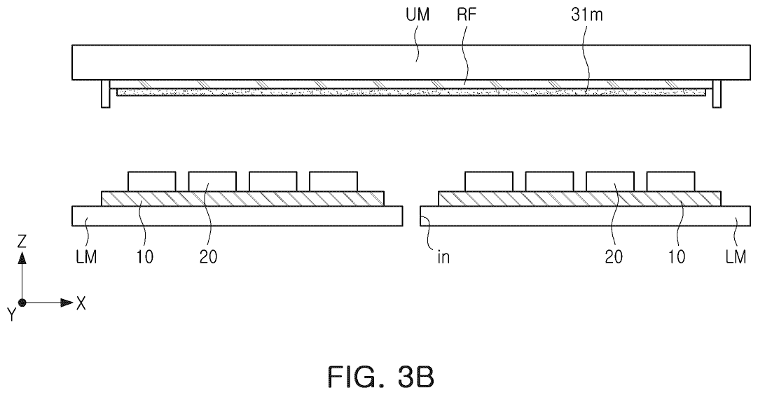

FIGS. 3A and 3B are diagrams illustrating an operation S102 of FIG. 1. Referring to FIGS. 3A and 3B, a release film RF to which a first encapsulant 31m is attached may be provided on the upper mold UM.

The upper mold UM may be a mold opposing the lower mold LM, and may be configured to cover an upper portion of the substrate strip 10. The upper mold UM may include a dam structure for controlling a flow of an encapsulant. The release film RF may be provided to (for example, on) a lower surface of the upper mold UM. The release film RF may be provided on the upper mold UM by rotation of a roller disposed on one side or opposite sides of the upper mold UM.

The release film RF may include, for example, a thermosetting polymer and/or a photocurable polymer. For example, the release film RF may include a fluorinated ethylene propylene (FEP) film, fluorine-impregnated glass cloth, a polyethylene terephthalate (PET) film, an ethylene tetrafluoro ethylene (ETE) film, a polypropylene (PP) film, a polyvinylidene chloride (PVDC) film, and/or the like, but example embodiments are not limited thereto.

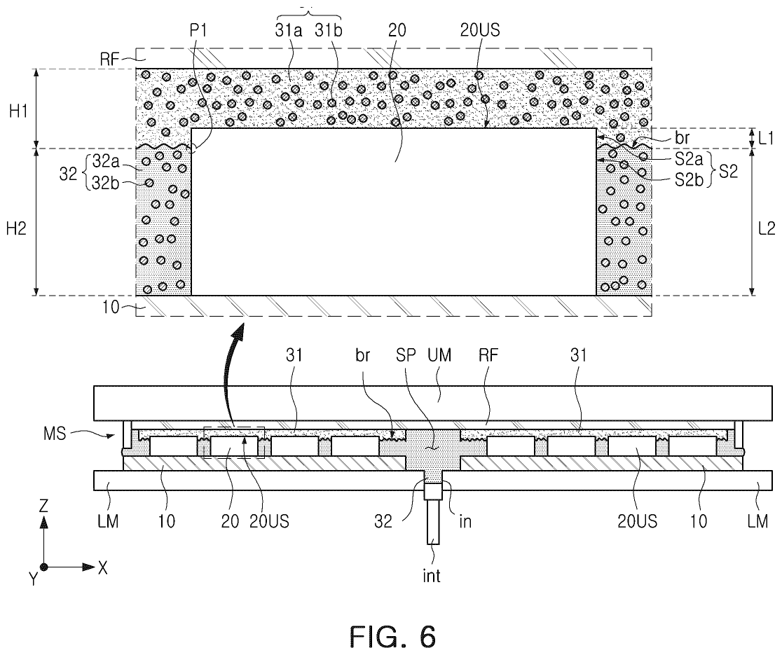

The first encapsulant 31m may be attached to a lower surface of the release film RF in, for example, the form of a film, but example embodiments are not limited thereto. In some example embodiments, the first encapsulant 31m may be, for example, disposed in a high viscosity paste form. The first encapsulant 31m may be provided onto the upper mold UM in a state of being attached to the lower surface of the release film RF. The number of first encapsulants 31m may be, for example provided to correspond to the number of substrate strips 10 (see, for example, FIG. 3A). In some example embodiments, the first encapsulant 31m may be provided as a single film having an area covering all of the plurality of substrate strips 10 (see, for example, FIG. 3B). The first encapsulant 31m may include, for example, a polymer compound and a filler for improving thermal conductivity, which will be described in detail with reference to FIG. 6.

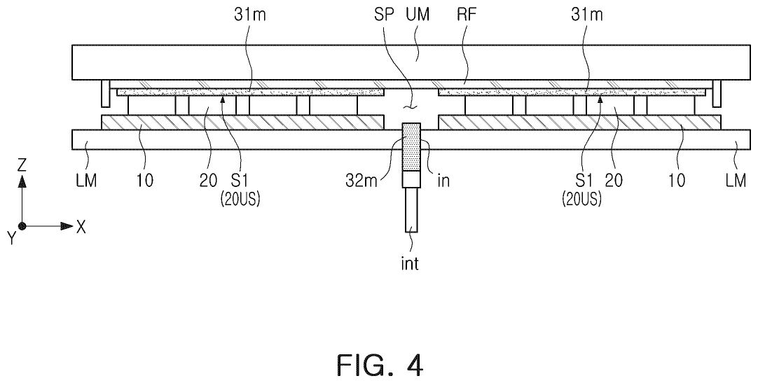

FIG. 4 is a diagram illustrating an operation S103 of FIG. 1.

Referring to FIG. 4, the upper mold UM and the lower mold LM may be proximate to each other.

The upper mold UM and the lower mold LM may be moved such that the first encapsulant 31m is aligned with the substrate strips 10. The upper mold UM and the lower mold LM may be allowed to be proximate to each other such that the first encapsulant 31m is adjacent to an upper surface 20US of each of the plurality of semiconductor chips 20. A lower surface S1 of the first encapsulant 31m may be in contact with the upper surface 20US of any or each of the plurality of semiconductor chips 20. When the plurality of semiconductor chips 20 include stack chips stacked in the vertical direction (for example, according to some example embodiments relating to FIG. 11), the lower surface S1 of the first encapsulant 31m may be in contact with an upper surface 20US of an uppermost stack chip.

In addition, a second encapsulant 32m may be provided into the upper mold UM and the lower mold LM through the injection hole in. The second encapsulant 32m may be provided via a space SP between (for example, defined or at least partially defined between) the upper mold UM and the lower mold LM by an injection tool int such as, for example, a pin, a nozzle, or the like. The upper mold UM and/or the lower mold LM may be, for example, configured to heat the space SP therebetween. In some example embodiments, the space SP between the upper mold UM and the lower mold LM may provide (for example, accommodate) the second encapsulant 32m, and at the same time may also be heated to a temperature (for example, 150° C. or higher) at which the second encapsulant 32m may flow. The second encapsulant 32m may include a polymer compound and a filler for improving filling properties, which will be described in detail with reference to FIG. 6.

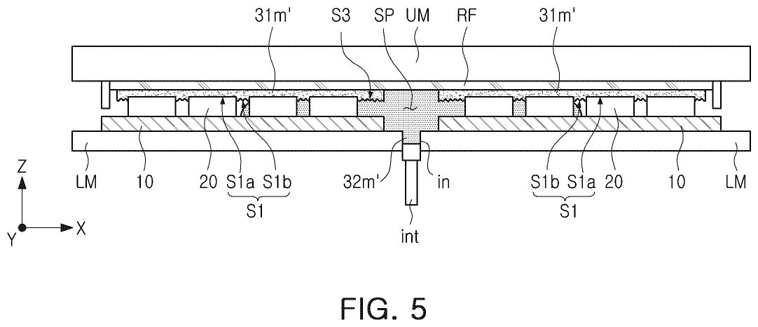

FIG. 5 is a diagram illustrating an operation S104 of FIG. 1.

Referring to FIG. 5, a first encapsulant 31m′ and a second encapsulant 32m′ may flow.

A space SP between the lower mold LM and the upper mold UM may be heated to 150° C. or higher, but example embodiments are not limited thereto. For example, the heated first encapsulant 31m′ may flow in a first direction toward the substrate strip 10, and the heated second encapsulant 32m′ may flow in a second direction, perpendicular to the first direction. According to some example embodiments, the first encapsulant 31m′ and the second encapsulant 32m′ including different materials may simultaneously flow before being cured, thereby improving productivity and improving adhesion between the different materials and reliability, as compared to a case in which encapsulants including different materials are formed in individual processes.

The first encapsulant 31m′ that is in a solid (film) state may have reduced viscosity in a temperature atmosphere of the internal space SP, and may flow downwardly to cover or at least partially cover side surfaces of the plurality of semiconductor chips 20. A lower surface S1 of the first encapsulant 31m′ may include a first portion S1a in contact with upper surfaces of the plurality of semiconductor chips 20, and a second portion S1b positioned between the plurality of semiconductor chips 20, the second portion S1b forming a contact surface S3 with the second encapsulant 32m′. The second portion S1b of the first encapsulant 31m′ may be positioned on (for example, at) a level lower than that of the upper surfaces of the plurality of semiconductor chips 20, but example embodiments are not limited thereto.

The second encapsulant 32m′, injected through the injection hole in a solid or liquid state, may have reduced viscosity in a temperature atmosphere of the internal space SP, and may flow to a space between the substrate strip 10 and the first encapsulant 31m′. The heated second encapsulant 32m′ may flow in opposite directions of the injection hole in.

FIG. 6 is a diagram illustrating an operation S105 of FIG. 1.

Referring to FIG. 6, a molded structure MS may be formed. The molded structure MS may include a substrate strip 10, a plurality of semiconductor chips 20, and a first encapsulating layer 31 and a second encapsulating layer 32 encapsulating the substrate strip 10 and the plurality of semiconductor chips 20.

The first encapsulating layer 31 and the second encapsulating layer 32 may be stacked on the substrate strips 10. The first encapsulating layer 31 and the second encapsulating layer 32 may be formed by curing the first encapsulant 31m and the second encapsulant 32m, respectively. The first encapsulating layer 31 may be formed by the first encapsulant 31m flowing in a direction toward the lower mold LM. The second encapsulating layer 32 may be formed by the second encapsulant 32m flowing toward opposite sides of the injection hole in.

Due to a flow of the heated first encapsulant 31m′, an interface br between (for example, of) the first encapsulating layer 31 and the second encapsulating layer 32 may be positioned on (for example, at) a level lower than that of the upper surface 20US of each of the plurality of semiconductor chips 20. The interface br between the first encapsulating layer 31 and the second encapsulating layer 32 may abut (for example, contact) a side surface S2 of any or each of the plurality of semiconductor chips 20. The interface br between the first encapsulating layer 31 and the second encapsulating layer 32 may include contact points P1 in contact with (for example, individually or respectively in contact with) the side surface S2 of each of the plurality of semiconductor chips 20. A first distance (for example, “H1”) from the substrate strip 10 to the interface br between the first encapsulating layer 31 and the second encapsulating layer 32 may be less than a second distance (for example, “L1+L2”) from the substrate strip 10 to the upper surface 20US of each of the plurality of semiconductor chips 20.

A height H1 of the first encapsulating layer 31 may be less than a height H2 of the second encapsulating layer 32. The side surface S2 of each of the plurality of semiconductor chips 20 may include an upper side surface S2a in contact with the first encapsulating layer 31, and a lower side surface S2b in contact with the second encapsulating layer 32. The first encapsulating layer 31 may be in contact with the upper surface 20US and the upper side surface S2a of each of the plurality of semiconductor chips 20, and the second encapsulating layer 32 may be in contact with the lower side surface S2b of each of the plurality of semiconductor chips 20. A length L1 of the upper side surface S2a of each of the plurality of semiconductor chips 20 may be less than a length L2 of the lower side surface S2b of each of the plurality of semiconductor chips 20.

In some example embodiments, a thermal conductivity of the first encapsulating layer 31 may be greater than that of the second encapsulating layer 32. For example, the thermal conductivity of the first encapsulating layer 31 may be within a range of about 1 W/mK to about 4 W/mK, and the thermal conductivity of the second encapsulating layer 32 may be within a range of about 8 W/mK to about 12 W/mK. The first encapsulant 31 may include a first polymer compound 31a and a first filler 31b. The second encapsulant 32 may include a second polymer compound 32a and a second filler 32b having a type different from that of the first filler 31b. The first polymer compound 31a and the second polymer compound 32a may include, for example, a thermosetting resin such as an epoxy resin, a thermoplastic resin such as polyimide, or a prepreg, an Ajinomoto build-up film (ABF), a fire retardant (FR), a bismaleimide-triazine (BT), an epoxy molding compound (EMC), and/or the like, but example embodiments are not limited thereto. A thermal conductivity of the first filler 31b may be greater than that of the second filler 32b. For example, the first filler 31b may include alumina (Al₂O₃), and the second filler 32b may include silica (SiO₂), but example embodiments are not limited thereto.

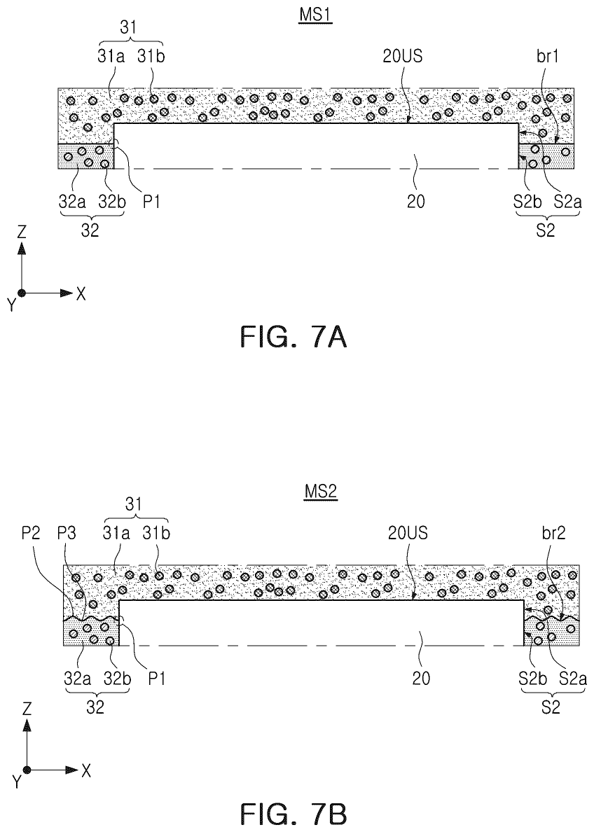

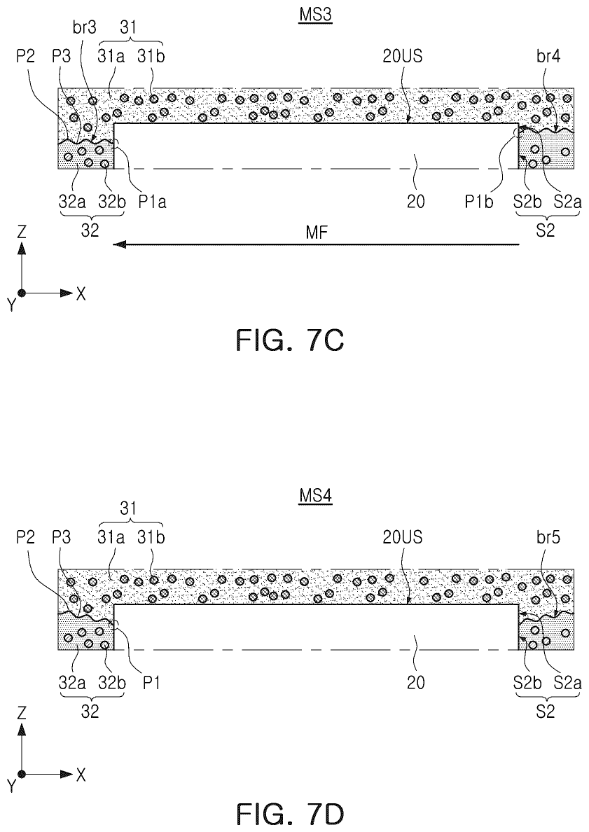

FIGS. 7A to 7D are diagrams illustrating a molded structure according to some example embodiments.

Referring to FIG. 7A, in a molded structure MS1 according to some example embodiments, at least a portion br1 of an interface br between a first encapsulating layer 31 and a second encapsulating layer 32 may be a flat surface extending in a direction, intersecting a side surface S2 of each of a corresponding plurality of semiconductor chips 20. In some example embodiments, when a flow of a heated first encapsulant 31m′ is low, at least a portion br1 of the interface br between the first encapsulating layer 31 and the second encapsulating layer 32 may extend in a direction, parallel to the upper surface 20US of each of the plurality of semiconductor chips 20. The at least a portion br1 of the interface br between the first encapsulating layer 31 and the second encapsulating layer 32 may be positioned on a level, lower than that of an upper surface 20US of each of the plurality of semiconductor chips 20. The at least a portion br1 of the interface br between the first encapsulating layer 31 and the second encapsulating layer 32 may include a contact point P1 in contact with the side surfaces S2 of each of the plurality of semiconductor chips 20.

Referring to FIG. 7B, in a molded structure MS2 according to some example embodiments, at least a portion br2 of a interface br between a first encapsulating layer 31 and a second encapsulating layer 32 may have a curvature formed by a flow of a heated first encapsulating material 31m′. For example, the at least a portion br2 of the interface br between the first encapsulating layer 31 and the second encapsulating layer 32 may be a curved surface (or a wave or wavy surface) in which a peak P2 and a valley P3 are alternately repeated in a horizontal direction (X-and Y-directions). The peak P2 and the valley P3 may be repeated at a regular or irregular interval. A plurality of peaks P2 and a plurality of valleys P3 may be formed to have an irregular level. For example, the plurality of peaks P2 may be positioned on different levels, and the plurality of valleys P3 may be positioned on different levels. Both the peak P2 and the valley P3 may be positioned on (for example, at) a level lower than that of an upper surface 20US of each of a plurality of semiconductor chips 20, but example embodiments are not limited thereto. In some example embodiments, the peak P2 may be positioned on a level, higher than or the same as that of the upper surface 20US of each of the plurality of semiconductor chips 20.

Referring to FIG. 7C, in a molded structure MS3 according to some example embodiments, at least portions br3 and br4 of an interface br between a first encapsulating layer 31 and a second encapsulating layer 32 may have different vertical levels. The interface br between the first encapsulating layer 31 and the second encapsulating layer 32 may include a first interface br3 and a second interface br4, spaced apart from each other. The first interface br3 may include a first contact P1a in contact with a side surface S2 of a corresponding semiconductor chip 20 on a first level. The second interface br4 may include a second contact P1b in contact with a side surface S2 of a corresponding semiconductor chip 20 on a second level, different from the first level. For example, a level of the interface br between the first encapsulating layer 31 and the second encapsulating layer 32 may be further lowered in a flow direction MF of the second encapsulant 32m′ illustrated in FIG. 5. The first contact P1a may be positioned on a level, lower than that of the second contact P1b. However, the present inventive concepts are not limited thereto, and, for example, levels of the first interface br3 and the second interface br4, spaced apart from each other, may be formed irrespective of the flow direction MF of the second encapsulant 32m′.

Referring to FIG. 7D, in a molded structure MS4 according to some example embodiments, at least a portion br5 of an interface br between a first encapsulating layer 31 and a second encapsulating layer 32 may have an inclination angle with respect to a side surface S2 of a corresponding semiconductor chip 20. The at least a portion br5 of the interface br between the first encapsulating layer 31 and the second encapsulating layer 32 may obliquely extend from the side surface S2 of the semiconductor chip 20. For example, the at least a portion br5 of the interface br between the first encapsulating layer 31 and the second encapsulating layer 32 may extend diagonally upwardly from the side surface S2 of the semiconductor chip 20.

A molded structure manufactured according to some example embodiments may have interfaces br between first encapsulating layers 31 and second encapsulating layers 32 having various forms, as described with reference to FIGS. 7A to 7D. For example, in a single molded structure MS, an interface br between a first encapsulating layer 31 and a second encapsulating layer 32 may include a portion in which one or two or more of the modifications illustrated in FIGS. 7A to 7D are combined. The interface br between the first encapsulating layer 31 and the second encapsulating layer 32 may have various forms according to, for example, fluidity, a flow direction, and the like of am encapsulant, in addition to those illustrated in FIGS. 7A to 7D.

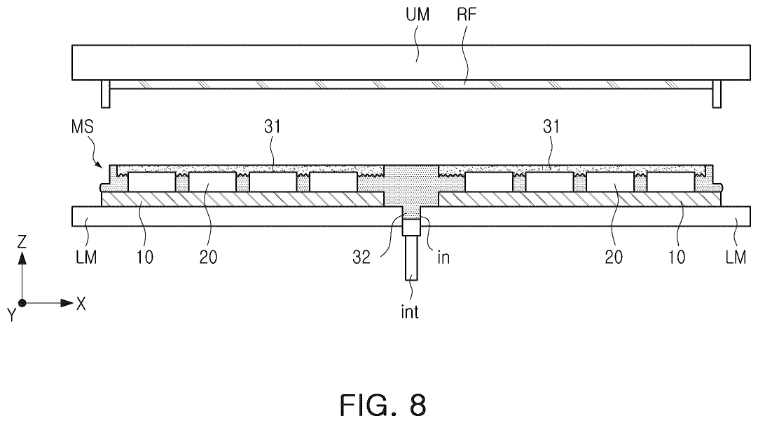

FIG. 8 is a diagram illustrating an operation S106 of FIG. 1.

Referring to FIG. 8, the molded structure MS may be separated from the release film RF. The molded structure MS may be separated by removing or reducing adhesive force of the release film RF and then allowing the upper mold UM and the lower mold LM to be spaced apart from each other. The release film RF may lose adhesive force by irradiating ultraviolet light or the like. The molded structure MS may include the plurality of substrate strips 10 integrated (for example, encapsulated) by the first encapsulating layer 31 and/or the second encapsulating layer 32. The first encapsulating layer 31 may have a lower surface in contact with upper surfaces of the plurality of semiconductor chips 20, and a flat upper surface exposed from the second encapsulating layer 32, but example embodiments are not limited thereto.

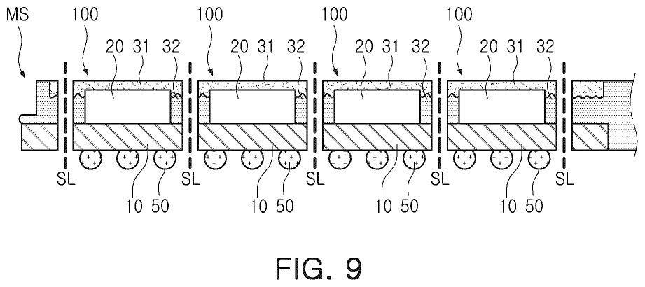

FIG. 9 is a diagram illustrating an operation S107 of FIG. 1.

Referring to FIG. 9, the molded structure MS may be cut into a plurality of semiconductor packages 100. The plurality of semiconductor packages 100 may include a substrate strip 10 separated into package substrate units, a semiconductor chip 20, a first encapsulating layer 31 covering (for example, at least partially covering) an upper surface and a portion of a side surface of the semiconductor chip 20, and a second encapsulating layer 32 covering a remaining portion of the side surface of the semiconductor chip 20. The molded structure MS may be cut using, for example, a sawing process using a laser drill, a blade, or the like, but example embodiments are not limited thereto.

In some example embodiments, an operation of attaching a plurality of connection bumps 50 to the substrate strip 10 before cutting the molded structure MS may be further included. A plurality of connection bumps 50 may be attached to a bottom surface of the substrate strip 10. The plurality of connection bumps 50 may include a low melting point metal, for example, tin (Sn) or an alloy including tin (Sn) (for example, Sn—Ag—Cu, Sn—Ag, or the like), but example embodiments are not limited thereto. In some example embodiments, the plurality of connection bumps 50 may be in the form of a combination of a pillar and a ball.

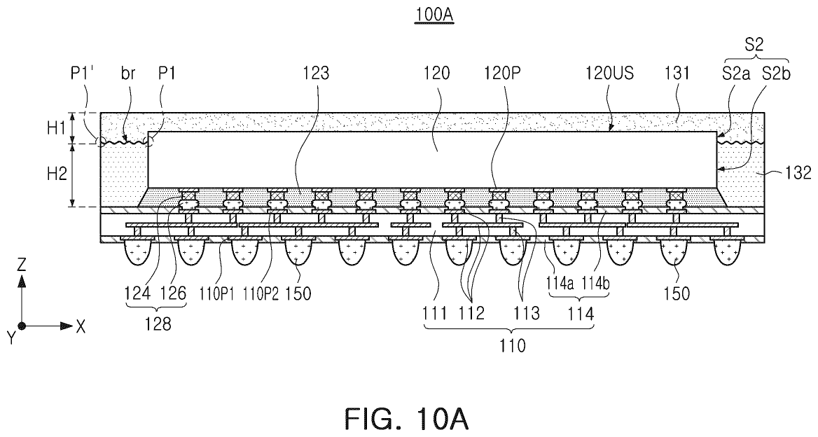

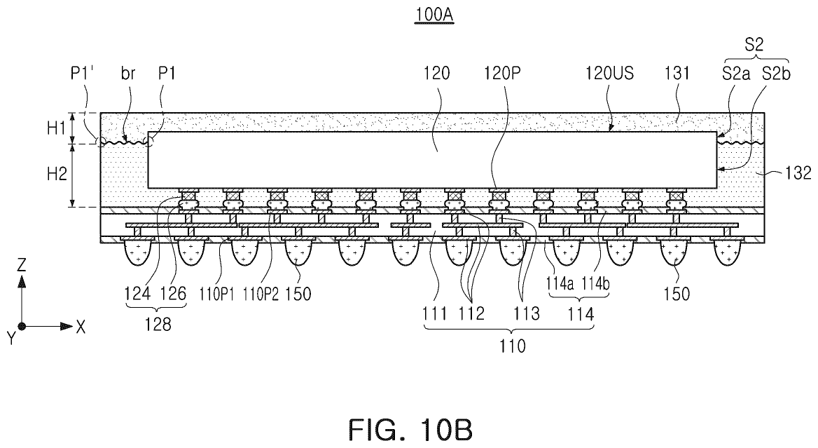

FIGS. 10A and 10B are diagrams illustrating a semiconductor package manufactured according to some example embodiments.

FIG. 11 is a diagram illustrating a semiconductor package manufactured according to some example embodiments.

Referring to FIGS. 10A and 10B, a semiconductor package 100A according to some example embodiments may include a package substrate 110, at least one semiconductor chip 120, a first molded layer 131, a second molded layer 132, and connection bumps 150.

The package substrate 110 may be or include a substrate for a semiconductor package including for example, a printed circuit board (PCB), a ceramic substrate, a glass substrate, a tape interconnection substrate, and/or the like. For example, the substrate 110 may be or include a double-sided PCB or a multilayer PCB, but example embodiments are not limited thereto. The package substrate 110 may include an insulating layer 111, interconnection patterns 112, and interconnection vias 113.

The insulating layer 111 may include, for example, a thermosetting resin such as, form example, an epoxy resin, a thermoplastic resin such as polyimide, or a prepreg, an ABF, FR-4, and/or the like including an inorganic filler and/or a glass fiber (or glass cloth or glass fabric), but example embodiments are not limited thereto. The insulating layer 111 may include a plurality of insulating layers stacked in a vertical direction, but example embodiments are not limited thereto. For example, the insulating layer 111 may include a core layer and a build-up layer stacked on upper and/or lower surfaces of the core layer, but example embodiments are not limited thereto. In some example embodiments,, the plurality of insulating layers may have an unclear boundary therebetween. In some example embodiments, the insulating layer 111 may include a photosensitive resin such as, for example, a photoimageable dielectric (PID).

The interconnection patterns 112 may form an electrical connection path in the insulating layer 111. The interconnection patterns 112 may include, for example, at least one metal or an alloy including two or more metals among, for example, copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon the, but example embodiments are not limited thereto. Any or each of the interconnection patterns 112 may be formed of, for example, an electrically deposited (ED) copper foil, a rolled-annealed (RA) copper foil, an ultra-thin copper foil, sputtered copper, a copper alloy, or the like, but example embodiments are not limited thereto. The interconnection patterns 112 may include a plurality of pattern layers, spaced apart from each other in the vertical direction. Each of the pattern layers may extend in a horizontal direction on each vertical level. The interconnection patterns 112 may include pattern layers fewer or more than those illustrated in the drawings. The interconnection patterns 112 may include lower connection terminals 110P1 and upper connection terminals 110P2. The lower connection terminals 110P1 may be pad portions of lowermost interconnection patterns 112, and the upper connection terminals 110P2 may be pad portions of uppermost interconnection patterns 112.

The interconnection vias 113 may electrically connect the interconnection patterns 112 to each other in the insulating layer 111. The interconnection vias 113 may include, for example, at least one metal or an alloy including two or more metals among, for example, copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and/or carbon (C), but example embodiments are not limited thereto. The interconnection vias 113 may be formed by, for example, filling (for example, entirely filling) a via hole passing through at least a portion of the insulating layer 111 with a conductive material, and/or conformally extending a conductive material along a wall of the via hole, but example embodiments are not limited thereto. In some example embodiments, at least a portion of the interconnection vias 113 may be formed in a form in which a conductive material is coated along the wall of the via hole, and an internal space of the via hole surrounded by the conductive material is filled with an insulating material.

The package substrate 110 may further include a protective layer 114. The protective layer 114 may be formed on an upper surface and/or a lower surface of the insulating layer 111. For example, the protective layer 114 may include a lower protective layer 114a and an upper protective layer 114b. The lower protective layer 114a may include an opening exposing at least a portion of the lower connection terminals 110P1. The upper protective layer 114b may include an opening exposing at least a portion of the upper connection terminals 110P2. The protective layer 114 may be formed using, for example, solder resist, but example embodiments are not limited thereto.

The at least one semiconductor chip 120 may be disposed such that an active surface on which connection pads 120P are disposed faces the package substrate 110. The at least one semiconductor chip 120 may be provided as a plurality of semiconductor chips arranged in a vertical direction and/or a horizontal direction. The at least one semiconductor chip 120 may be electrically connected to upper connection terminals 112P2 through conductive bumps 128. The conductive bumps 128 may, for example, include a pillar portion 124 and a solder portion 126, but example embodiments are not limited thereto. The pillar portion 124 may include, for example, copper (Cu) or an alloy of copper (Cu), and the solder portion 126 may include a low melting point metal, for example, tin (Sn) or an alloy (for example, Sn—Ag—Cu) including tin (Sn), but example embodiments are not limited thereto. In some example embodiments, the conductive bumps 128 may include only the pillar portion 124 or only the solder portion 126. The conductive bumps 128 may be surrounded by an underfill portion 123. The underfill portion 123 may have, for example, a capillary underfill (CUF) structure (see FIG. 10A). However, example embodiments are not limited thereto, and in some example embodiments, the underfill portion 123 may have a mole underfill (MUF) structure integrated with the second encapsulating layer 132 (see, for example, FIG. 10B).

The at least one semiconductor chip 120 may be or include a bare semiconductor chip without a bump or an interconnection layer, but the present inventive concepts are not limited thereto, and the at least semiconductor chip 120 may be or include a packaged-type semiconductor chip. The at least one semiconductor chip 120 may include, for example, a semiconductor wafer including a semiconductor element such as, for example, silicon or germanium, or a compound semiconductor such as silicon carbide (SiC), gallium arsenide (GaAs), indium arsenide (InAs), and indium phosphide (InP), and an integrated circuit (IC) formed on the semiconductor wafer, but example embodiments are not limited thereto*.

The at least one semiconductor chip 120 may be or include a logic chip including a central processing unit (CPU), a graphics processing unit (GPU), a field programmable gate array (FPGA), an application processor (AP), a digital signal processor, a cryptographic processor, a microprocessor, a microprocessor, a microcontroller, an analog-to-digital converter, an application-specific IC (ASIC), and/or the like. In some example embodiments, the at least one semiconductor chip 120 may further include a volatile memory such as a dynamic RAM (DRAM), a static RAM (SRAM), and a non-volatile memory such as a phase change RAM (PRAM), a magnetic RAM (RRAM), and/or a flash memory.

The first molded layer 131 and the second molded layer 132 may be formed of, for example, an EMC, may include, for example, different types of fillers. The first molded layer 131 may cover or at least partially cover an upper surface 120US and an upper side surface S2a of the semiconductor chip 120. The second molded layer 132 may cover or at least partially cover a lower side surface S2b of the semiconductor chip 120. For example, the upper surface 120US of the semiconductor chip 120 may be understood as an upper surface of an uppermost semiconductor chip, among a plurality of semiconductor chips stacked in the vertical direction. An interface br between the first molded layer 131 and the second molded layer 132 may be, for example, positioned on a level lower than that of the upper surface 120US of the semiconductor chip 120, but example embodiments are not limited thereto. The interface br between the first molded layer 131 and the second molded layer 132 may be, for example, a curved surface, abutting (for example, touching) the side surface S2 of the semiconductor chip 120.

The interface br between the first molded layer 131 and the second molded layer 132 may include a first contact P1 in contact with the side surface S2 of the semiconductor chip 120, and a second contact Pl' in contact with external surfaces of the first and second molded layers, and may be a curved surface in which a peak and a valley are repeated in a single direction (for example, an X direction), intersecting the side surface S2 of the semiconductor chip 120, between the first contact P1 and the second contact P1′. In some example embodiments, the single direction may be a direction parallel to the upper surface 120US of the semiconductor chip 120. The interface br between the first molded layer 131 and the second molded layer 132 may, for example, extend at (for example, while having) a constant slope or a continuously changing slope, without a portion having a discontinuously changing slope, but example embodiments are not limited thereto.

A height H1 of the first molded layer 131 may be, for example, less than a height H2 of the second molded layer 132. A thermal conductivity of the first molded layer 131 may be, for example greater than that of the second molded layer 132. For example, a thermal conductivity of the first molded layer 131 may be within a range of about 1 W/mK to about 4 W/mK, and a thermal conductivity of the second molded layer 132 may be within a range of about 8 W/mK to about 12 W/mK, but example embodiments are not limited thereto. According to some example embodiments, the first molded layer 131 and the second molded layer 132 may be formed by, for example, simultaneously curing encapsulants including different materials, such that the first molded layer 131 and the second molded layer 132 may have relatively excellent interfacial adhesive force.

The connection bumps 150 may be disposed on the lower connection terminals 110P1 of the package substrate 110. The semiconductor package 100A may be electrically connected to an external device such as, for example, a module substrate, a main board, or the like through the connection bumps 150. The connection bumps 150 may include, for example, tin (Sn) or an alloy (for example, Sn—Ag—Cu, Sn—Ag, or the like) including tin (Sn), but example embodiments are not limited thereto.

Referring to FIG. 11, a semiconductor package 100B according to some example embodiments may include components substantially the same as or similar to those of the semiconductor package 100A illustrated in, for example FIG. 10B, except that the semiconductor package 100B according to the some example embodiments includes a semiconductor chip 120 (hereinafter, referred to as a “chip stack”) mounted in a wire-bonding manner. Accordingly, components, corresponding to each other, are denoted by the same or similar reference numerals, and repeated descriptions will be omitted below.

A chip stack 120 may be mounted on a package substrate 110. The chip stack 120 may include a plurality of stack chips SC1, SC2, SC3, and SC4. The plurality of stack chips SC1, SC2, SC3, and SC4 may be electrically connected to the package substrate 110 in, for example, a wire bonding manner. The plurality of stack chips SC1, SC2, SC3, and SC4 may be attached to the package substrate 110 and other ones of stack chips SC1, SC2, SC3, and SC4 vertically adjacent to the package substrate 110 by an adhesive film 121. The adhesive film 121 may include, for example, an inorganic adhesive and/or a polymer adhesive. The polymer adhesive may include, for example, a thermosetting resin, a thermoplastic resin, or a hybrid resin mixed therewith, but example embodiments are not limited thereto. Connection pads 120P of each (for example, of respective ones) of the plurality of stack chips SC1, SC2, SC3, and SC4 may be electrically connected to upper connection terminals 110P2 of the package substrate 110 through (for example, by) a bonding wire 122.

The plurality of stack chips SC1, SC2, SC3, and SC4 may be, for example, memory chips. The plurality of stack chips SC1, SC2, SC3, and SC4 may be or include a non-volatile memory semiconductor device such as, for example, a flash memory, a phase-change random access memory (PRAM), a magnetoresistive random access memory (MRAM), a ferroelectric random access memory (FeRAM), and a resistive random access memory (RRAM), and/or a volatile memory device such as a dynamic random access memory (DRAM) and a static random access memory (SRAM), but example embodiments are not limited thereto. The flash memory may be, for example, a V-NAND flash memory, but example embodiments are not limited thereto. The plurality of stack chips SC1, SC2, SC3, and SC4 may be shifted in at least one direction such that at least a portion of any or each of the connection pads 120P is exposed upwardly (for example, such that an a portion of an upper surface thereof is exposed), but a form in which the plurality of stack chips SC1, SC2, SC3, and SC4 are stacked is not limited to those illustrated in the drawings. The plurality of stack chips SC1, SC2, SC3, and SC4 may be electrically connected to each other through the bonding wire 122.

In some example embodiments, the semiconductor package 100B may further include a control semiconductor chip for the plurality of stack chips SC1, SC2, SC3, and SC4. The control semiconductor chip may include, for example, a logic device, a FET such as a planar FET or a FinFET, AND, OR, NOT, and/or the like, various active devices such as a system LSI, CIS, and MEMS, and/or a passive device. The control semiconductor chip may, for example, control access to data stored in the plurality of stack chips SC1, SC2, SC3, and SC4. The control semiconductor chip may, for example, control write/read operations of the plurality of stack chips SC1, SC2, SC3, and SC4 according to a control command of an external host. The control semiconductor chip may perform for example, wear leveling, garbage collection, bad block management, and/or error correction code (ECC). The control semiconductor chip may be disposed to be spaced apart from the plurality of stack chips SC1, SC2, SC3, and SC4, but the present inventive concepts are not limited thereto.

The first molded layer 131 may cover or at least partially cover an upper surface 120US and an upper side surface S2a of an uppermost stack chip SC4, among the plurality of stack chips SC1, SC2, SC3, and SC4. The first molded layer 131 may cover at least a portion of the bonding wire 122 that is protruding further than the upper surface 120US of the uppermost stack chip SC4. The second molded layer 132 may cover or at least partially cover a lower side surface S2b of the uppermost stack chip SC4. An interface br between the first molded layer 131 and the second molded layer 132 may be positioned on (for example, at) a level lower than that of the upper surface 120US of the uppermost stack chip SC4. A height H1 of the first molded layer 131 may be less than a height H2 of the second molded layer 132, but example embodiments are not limited thereto.

According to some example embodiments of the present inventive concepts, encapsulating layers including different materials may be formed using a single process, thereby providing a method of manufacturing a semiconductor package having improved productivity and reliability, and a semiconductor package.

While some example embodiments have been shown and described above, it will be apparent to those ordinarily skilled in the art that modifications and variations could be made without departing from the spirit and scope of the present inventive concepts as in the appended claims.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

1. A method of manufacturing a semiconductor package, the method comprising:
disposing a substrate strip on a lower mold, the substrate strip having plurality of semiconductor chips arranged in a horizontal direction thereon;
providing a release film on an upper mold, the release film having a first encapsulant attached thereto;
allowing the upper mold and the lower mold to be proximate to each other such that the first encapsulant is adjacent to an upper surface of each of the plurality of semiconductor chips;
injecting a second encapsulant into a space at least partially defined between the upper mold and the lower mold;
heating the first encapsulant and the second encapsulant to form a molded structure, the molded structure including a first encapsulating layer and a second encapsulating layer that are stacked on the substrate strip, the first encapsulant forming the first encapsulating layer, and the second encapsulant forming the second encapsulating layer;
allowing the upper mold and the lower mold to be spaced from each other such that the molded structure is separated from the release film; and
cutting the molded structure,
wherein a first distance is less than a second distance, the first distance being from the substrate strip to an interface between the first encapsulating layer and the second encapsulating layer and the second distance being from the substrate strip to an upper surface of the plurality of semiconductor chips.

2. The method of claim 1, wherein the first encapsulant is attached to a lower surface of the release film in the form of a film and faces the substrate strip.

3. The method of claim 1, wherein the upper mold and the lower mold are allowed to be proximate to each other such that the first encapsulant is in contact with the upper surface of each of the plurality of semiconductor chips.

4. The method of claim 1, wherein
each of the plurality of semiconductor chips includes stack chips stacked in a vertical direction, and
the upper mold and the lower mold are allowed to be proximate to each other such that the first encapsulant is in contact with an upper surface of an uppermost stack chip, among the stack chips.

5. The method of claim 1, wherein
the first encapsulant includes a first filler, and
the second encapsulant includes a second filler, the second filler being of a different type than the first filler.

6. The method of claim 5, wherein a thermal conductivity of the first filler is greater than that of the second filler.

7. The method of claim 5, wherein
the first filler includes alumina (Al₂O₃), and
the second filler includes silica (SiO₂).

8. The method of claim 1, wherein
the heated first encapsulant flows in a first direction toward the substrate strip, and
the heated second encapsulant flows in a second direction that is perpendicular to the first direction.

9. The method of claim 1, wherein the interface between the first encapsulating layer and the second encapsulating layer includes contact points, the contact points respectively in contact with side surfaces of the plurality of semiconductor chips.

10. The method of claim 1, wherein the interface between the first encapsulating layer and the second encapsulating layer is a curved surface in which a peak and a valley are repeated in a horizontal direction.

11. The method of claim 1, wherein a height of the first encapsulating layer is less than a height of the second encapsulating layer.

12. The method of claim 1, wherein the interface between the first encapsulating layer and the second encapsulating layer extends in a direction that is parallel to the upper surface of the plurality of semiconductor chips.

13. The method of claim 1, wherein
a thermal conductivity of the first encapsulating layer is within a range of 1 W/mK to 4 W/mK, and
a thermal conductivity of the second encapsulating layer is within a range of 8 W/mK to 12 W/mK.

14. The method of claim 1, further comprising:
attaching a plurality of connection bumps to the substrate strip before cutting the molded structure.

15. The method of claim 14, wherein the plurality of connection bumps includes tin (Sn) or an alloy including tin (Sn).

16. A method of manufacturing a semiconductor package, the method comprising:
disposing substrate strips on a lower mold, a plurality of semiconductor chips being arranged on the substrate strips, the substrate strips being on opposite sides of an injection hole at least partially defined by the lower mold;
providing a release film on an upper mold, a first encapsulant being attached to the release film;
allowing the upper mold and the lower mold to be proximate to each other such that the first encapsulant is aligned on the substrate strips;
injecting a second encapsulant through the injection hole; and
forming a first encapsulating layer and a second encapsulating layer by heating a space at least partially defined between the lower mold and the upper mold, the first encapsulating layer and the second encapsulating layer being stacked on the substrate strips,
wherein the first encapsulating layer is formed by the first encapsulant flowing in a direction toward the lower mold, and
the second encapsulating layer is formed by the second encapsulant flowing toward the opposite sides of the injection hole.

17. The method of claim 16, wherein
the first encapsulating layer is in contact with an upper surface and an upper side surface of each of the plurality of semiconductor chips, and
the second encapsulating layer is in contact with a lower side surface of each of the plurality of semiconductor chips.

18. The method of claim 17, wherein a length of the upper side surface of each of the plurality of semiconductor chips is less than a length of the lower side surface of each of the plurality of semiconductor chips.

19. The method of claim 16, wherein a thermal conductivity of the first encapsulating layer is greater than that of the second encapsulating layer.

20. A method of manufacturing a semiconductor package, the method comprising:
disposing a substrate strip on a lower mold, the substrate strip having plurality of semiconductor chips arranged thereon;
providing a release film on an upper mold, the release film having a first encapsulant attached thereto;
allowing the upper mold and the lower mold to be proximate to each other such that the first encapsulant is adjacent to the plurality of semiconductor chips;
injecting a second encapsulant into a space at least partially defined between the upper mold and the lower mold;
allowing the first encapsulant and the second encapsulant to simultaneously flow; and
forming a first encapsulating layer and a second encapsulating layer in which the first encapsulant and the second encapsulant are cured, respectively,
wherein an interface between the first encapsulating layer and the second encapsulating layer extends in a direction intersecting a side surface of the plurality of semiconductor chips.

21.-29. (canceled)
